(19) United States
(12) Patent Application Publication
(10) Pub. No.: US 2014/0306295 A1
(43) Pub. Date: Oct. 16, 2014

(54) SEMICONDUCTOR DEVICE AND METHOD FOR FABRICATING THE SAME

(71) Applicant: Samsung Electronics Co., Ltd., Suwon-si (KR)

(72) Inventor: Ju-Youn Kim, Suwon-si (KR)

(73) Assignee: Samsung Electronics Co., Ltd., Suwon-si (KR)

(21) Appl. No.: 14/105,627

(22) Filed: Dec. 13, 2013

(30) Foreign Application Priority Data
Apr. 10, 2013 (KR) 10-2013-0039465

(51) Int. Cl. H01L 29/51

(52) U.S. Cl. CPC H01L 29/517
USPC 257/401

(57) ABSTRACT

A semiconductor device includes a substrate including a first region and a second region. The semiconductor device also includes first and second gate laminated bodies respectively formed on the first region and the second region, wherein the first gate laminated body includes a first gate insulating film that is in contact with the substrate and that includes a first high-k dielectric film; a first lower laminated body on the first gate insulating film; and a first upper laminated body on the first lower laminated body. The first lower laminated body includes a titanium nitride film, an aluminum film, and a titanium nitride film, laminated in sequence; and the second gate laminated body includes a second gate insulating film in contact with the substrate and including a second high-k dielectric film. Additionally, a second laminated body is formed on the second gate insulating film.

### CROSS-REFERENCE TO RELATED APPLICATIONS

This application is based on and claims priority from Korean Patent Application No. 10-2013-0039465, filed on Apr. 10, 2013 in the Korean Intellectual Property Office, the disclosure of which is incorporated herein in its entirety by reference.

### BACKGROUND

1. Field of the Invention

The present inventive concepts relate to a semiconductor device and a method for fabricating the same.

2. Background

As the feature size of a metal-oxide semiconductor (MOS) transistor is decreased, the lengths of a gate and a channel that is formed below the gate are shortened. Accordingly, research has been conducted to increase capacitance between the gate and the channel and to improve operation characteristics of the MOS transistor.

As the thickness of a silicon oxide layer that is mainly used as a gate insulating film is reduced, the electrical properties thereof approach a physical limit. Accordingly, for replacement of the existing silicon oxide film, research for a high-k film having high dielectric constant has been actively conducted. The high-k film can reduce leakage current between a gate electrode and a channel region while maintaining thin equivalent oxide thickness.

Further, polysilicon that is mainly used as a gate material has higher resistance than most metal materials. Accordingly, the polysilicon gate electrode has been replaced by a metal gate electrode.

### SUMMARY

Semiconductor devices, described herein, may offer improved operation voltage characteristics. Additionally, methods of this disclosure enable fabrication of a semiconductor device having improved operation voltage characteristics.

Additional advantages, subjects, and features of the inventive concepts will be set forth, in part, in the description that follows and, in part, will become apparent to those having ordinary skill in the art upon examination of the following and/or may be learned from practice of the inventive concepts.

In one aspect of the inventive concepts, a semiconductor device includes a substrate including a first region and a second region; and first and second gate laminated bodies are respectively formed on the first region and the second region. The first gate laminated body includes a first gate insulating film formed in contact with the substrate, wherein the first gate insulating film includes a first high-k dielectric film, a first lower laminated body on the first gate insulating film, and a first upper laminated body on the first lower laminated body. The first lower laminated body includes a titanium nitride film, an aluminum film, and a titanium nitride film, stacked in the above-listed sequence. The second gate laminated body includes a second gate insulating film in contact with the substrate and including a second high-k dielectric film. A second laminated body formed on the second gate insulating film.

In additional embodiments, the first gate insulating film includes aluminum; and a concentration profile of the aluminum may include a maximal point and a minimal point in the first gate insulating film. Additionally, the aluminum may be piled up in the first gate insulating film to form a boundary with the substrate.

In additional embodiments, the first upper laminated body and the second laminated body comprise a metal oxide film and a metal nitride film, wherein the metal oxide film is between the metal nitride film and the first lower laminated body. The metal oxide film may include lanthanum oxide, and the metal nitride film may include titanium nitride. Additionally, the second gate insulating film may include lanthanum (La).

In additional embodiments, the first region includes a P-type transistor region, and the second region includes an N-type transistor region.

In additional embodiments, the second laminated body is formed at the same level as the first upper laminated body.

In another aspect of the present inventive concepts, a semiconductor device includes a first gate insulating film in contact with a substrate and doped with diffused metal, a second gate insulating film including a high-k dielectric film on the first gate insulating film, the diffused metal being doped in the high-k dielectric film, and a first laminated body including a diffused metal film on the second gate insulating film.

In additional embodiments, the diffused metal film includes aluminum (Al).

In additional embodiments, a concentration profile of the diffused metal includes a maximal point and a minimal point in the first gate insulating film and the second gate insulating film.

In additional embodiments, the first laminated body comprises metallic films respectively disposed on upper and lower portions of the diffused metal film. Additionally, the first laminated body may comprise a first titanium nitride (TiN) film, an aluminum (Al) film, and a second titanium nitride film, wherein the first titanium nitride film is between the second gate insulating film and the aluminum film, and wherein the aluminum film is between first and second titanium nitride films.

In additional embodiments, the semiconductor device further includes a second laminated body including a metal oxide film and a metallic film on the first laminated body. The second laminated body may include a lanthanum oxide (LaO) film and a titanium nitride film, wherein the lanthanum oxide film is between the first laminated body and the titanium nitride film.

In another aspect of the inventive concepts, a semiconductor device includes a substrate; a lower gate insulating film coated on the substrate and doped with aluminum; an upper gate insulating film coated on the lower gate insulating film, with the lower gate insulating film being sandwiched between the substrate and the upper gate insulating film, wherein the upper gate insulating film includes a dielectric film doped with aluminum, wherein the dielectric film has a dielectric constant higher than that of the substrate; and a laminated body including an aluminum film on the upper gate insulating film.

In additional embodiments, the laminated body further includes a first titanium nitride film and a second titanium nitride film, wherein the aluminum film is sandwiched between first and second titanium nitride films. Additionally, the laminated body on the upper gate insulation film may be a lower laminated body, and the device may further include an upper laminated body including a metal oxide film and a metallic film on the lower laminated body, wherein the metal oxide film is sandwiched between the metallic film and the lower laminated body.

In additional embodiments, the device is free of a silicon-germanium layer, which was used between the substrate and gate insulation film in previous devices. Without a cSiGe layer, semiconductor devices described herein may offer improved operation voltage characteristics.

### BRIEF DESCRIPTION OF THE DRAWINGS

The above and other features and advantages of the present inventive concepts will be more apparent from the following detailed description taken in conjunction with the accompanying drawings, in which:

FIG. 1 is a sectional view illustrating a semiconductor device according to a first embodiment of the present inventive concepts;

FIGS. 2A to 2C are graphs schematically illustrating the concentration profile of diffused metal in a gate insulating film of FIG. 1;

FIG. 3 is a sectional view illustrating a semiconductor device according to a second embodiment of the present inventive concepts;

FIGS. 4 and 5 are a circuit diagram and a layout diagram of a semiconductor device according to a third embodiment of the present inventive concepts;

FIG. 6 is a block diagram of an electronic system including a semiconductor device according to some embodiments of the present inventive concepts;

FIGS. 7 and 8 are exemplary views illustrating a semiconductor system that can adopt a semiconductor device according to some embodiments of the present inventive concepts; and

FIGS. 9 to 15 are sectional views of the device at intermediate steps in a method for fabricating a semiconductor device according to an embodiment of the present inventive concepts.

### DETAILED DESCRIPTION OF THE EMBODIMENTS

The present inventive concepts will now be described more fully hereinafter with reference to the accompanying drawings, in which preferred embodiments of the inventive concepts are shown. These inventive concepts may, however, be embodied in different forms and should not be construed as being limited to the embodiments set forth herein. Rather, these embodiments are provided so that this disclosure will sufficiently describe and enable the inventive concepts to those skilled in the art. The same reference numbers indicate the same components throughout the specification. In the attached figures, the thickness of layers and regions is exaggerated for clarity.

It will be understood that when an element or layer is referred to as being “connected to”, “coupled to”, or “on” another element or layer, it can be directly connected to, coupled to, or on another element or layer, or intervening elements or layers may be present. In contrast, when an element is referred to as being “directly connected to”, “directly coupled to” or “directly on” another element or layer, there are no intervening elements or layers present. As used herein, the term “and/or” includes any and all combinations of one or more of the associated listed items.

It will be understood that, although the terms, first, second, etc., may be used herein to describe various elements, these elements should not be limited by these terms. These terms are only used to distinguish one element from another element. Thus, for example, a first element, a first component or a first section, discussed below, could be termed a second element, a second component or a second section without departing from the teachings of the present invention.

The use of the terms, “a” and “an” and “the” and similar referents, in the context of describing the inventive concepts (especially in the context of the following claims) are to be construed to cover both the singular and the plural, unless otherwise indicated herein or clearly contradicted by context. The terms, “comprising,” “having,” “including,” and “containing”, are to be construed as being open-ended terms (i.e., meaning “including, but not limited to,”) unless otherwise noted.

Unless defined otherwise, all technical and scientific terms used herein have the same meaning as is commonly understood by one of ordinary skill in the art to which this inventive concepts belongs. It is noted that the use of any and all examples or exemplary terms, provided herein, is intended merely to better illuminate the inventive concepts and is not a limitation on the scope of the invention unless otherwise specified. Further, unless defined otherwise, all terms defined in generally used dictionaries may not be interpreted overly rigidly.

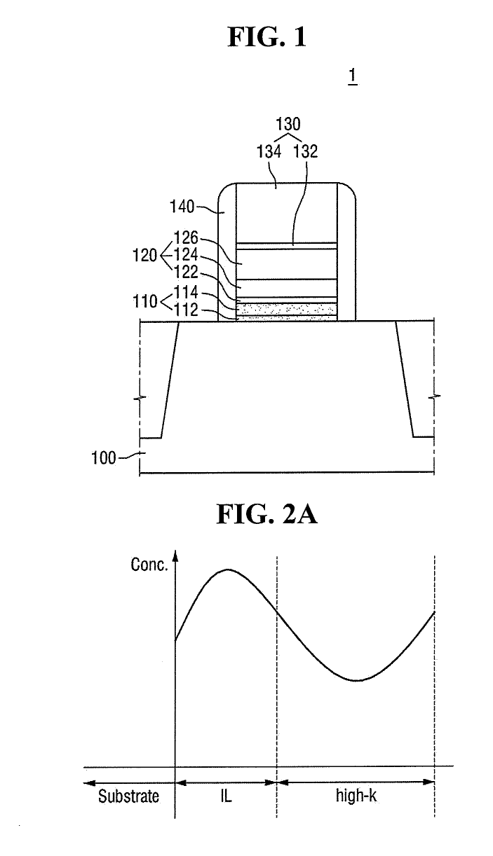

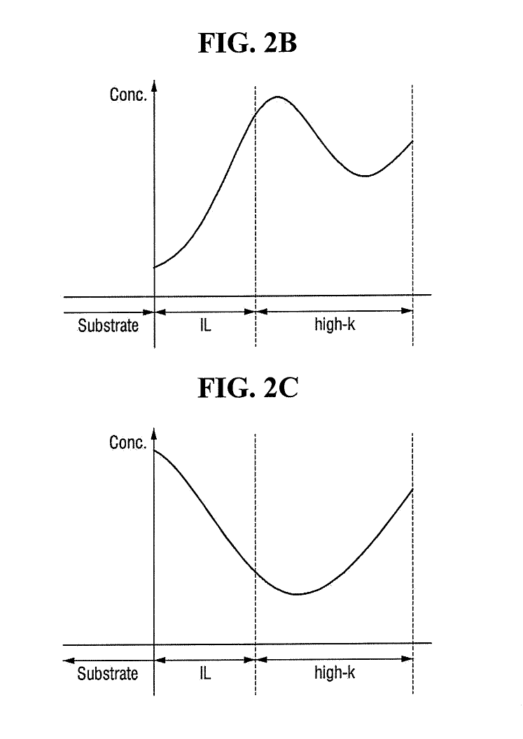

Hereinafter, referring to FIGS. 1 to 2C, a semiconductor device according to a first embodiment of the present inventive concepts will be described.

FIG. 1 is a view illustrating a semiconductor device according to a first embodiment of the present inventive concepts, and FIGS. 2A to 2C are graphs schematically illustrating the concentration profile of diffused metal in a gate insulating film of the semiconductor device.

Referring to FIG. 1, a semiconductor device 1 according to the first embodiment of the present inventive concepts includes a substrate 100, a first gate insulating film 110, a first lower laminated body 120, a first upper laminated body 130, and a first spacer 140.

The substrate 100 may be made of bulk silicon or silicon-on-insulator (SOI). While in some embodiments, the substrate 100 may be a silicon substrate; in additional embodiments, the substrate 100 may include other materials, such as indium antimonide, lead telluride, indium arsenide, indium phosphide, gallium arsenide, or gallium antimonide, but is not limited thereto. In the following description, it is assumed that the substrate 100 is a silicon substrate.

The first gate insulating film 110 is disposed on the substrate 100. The first gate insulating film 110 may include a high-k dielectric film [as used herein, “high-k” may refer to a dielectric constant higher than that of the substrate, e.g., higher than that of SiO2 (e.g., k>3.9)] and may include a first lower gate insulating film 112 and a first upper gate insulating film 114. Further, the first gate insulating film 110 may include diffused metal from the first lower laminated body 120, to be described later, and, in particular embodiments, may be doped with the diffused metal.

The first lower gate insulating film 112 is in contact with and disposed on the substrate 100. The first lower gate insulating film 112 may be an interlayer between the substrate 100 and the first upper gate insulating film 114 and may include, for example, a silicon oxide film.

The first upper gate insulating film 114 may include a high-k dielectric film. The high-k dielectric film may include, for example, at least one of the following: hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The first lower laminated body 120 is disposed on the first gate insulating film 110. The first lower laminated body 120 includes a diffused metal film 124. Further, the first lower laminated body 120 includes a first lower metallic film 122 and a first intermediate metallic film 126, which are respectively disposed on upper and lower portions of the diffused metal film 124. That is, the first lower laminated body 120 includes the first lower metallic film 122, the diffused metal film 124, and the first intermediate metallic film 126, which are sequentially laminated (i.e., sequentially stacked on one another) on the first gate insulating film 110.

The first lower metallic film 122 is formed on the first upper gate insulating film 114. The first lower metallic film 122 may include, for example, at least one of the following: titanium nitride (TiN), tantalum carbide (TaC), tantalum nitride (TaN), and tantalum carbonitride (TaCN).

The diffused metal film 124 is formed on the first lower metallic film 122. The diffused metal film 124 includes the same metal element as the diffused metal that is diffused and included in the first gate insulating film 110. The diffused metal film 124 may include, for example, aluminum (Al); and, in particular embodiments, the diffused metal film 124 may be an aluminum film.

The first intermediate metallic film 126 is formed on the diffused metal film 124. The first intermediate metallic film 126 may include, for example, at least one of the following: titanium nitride, tantalum carbide, tantalum nitride, and tantalum carbonitride.

The first lower laminated body 120 may include various combinations of the first lower metallic film 122 and the first intermediate metallic film 126. However, in the semiconductor device according to the first embodiment of the present inventive concepts, explanation will be made on the assumption that the first lower laminated body 120 includes a metal nitride film, an aluminum film, and a metal nitride film, which are sequentially laminated on the first gate insulating film 110. Hereinafter, explanation will be made on the assumption that the first lower laminated body 120 includes a structure in which a titanium nitride film, an aluminum film and a titanium nitride film are sequentially laminated.

The first upper laminated body 130 is arranged on the first lower laminated body 120. The first upper laminated body 130 may include a first insertion film 132 and a first upper metallic film 134. The first insertion film 132 and the first upper metallic film 134 are sequentially laminated on the first lower laminated body 120.

The first insertion film 132 is formed on the first intermediate metallic film 126. The first insertion film 132 may include, for example, lanthanum, and, in particular embodiments, lanthanum oxide (LaO).

The first upper metallic film 134 is formed on the first insertion film 132. The first upper metallic film 134 may include, for example, at least one of titanium nitride, tantalum carbide, tantalum nitride, and tantalum carbonitride.

The first upper laminated body 130 may include various combinations of the first insertion film 132 and the first upper metallic film 134. However, in the semiconductor device according to the first embodiment, explanation will be made on the assumption that the first upper laminated body 130 includes a metal oxide film and a metal nitride film, which are sequentially laminated on the first lower laminated body 120 (resulting in the metal oxide film being sandwiched between the metal nitride film and the first lower laminated body 120). Specifically, explanation will be made on the assumption that the first upper laminated body 130 included in the semiconductor device 1 includes a structure in which lanthanum oxide and titanium nitride are sequentially laminated.

The first lower laminated body 120 may be used as a work function adjustment film in a transistor that includes the first lower laminated body 120. Further, the first lower laminated body 120 and the first upper laminated body 130 may be used as a gate electrode of the transistor.

The first spacer 140 is disposed on a side wall of a gate laminated body that includes the gate insulating film 110, the first lower laminated body 120, and the first upper laminated body 130, which are sequentially laminated on the substrate 100. The first spacer 140 may include, for example, silicon oxide, silicon oxynitride, or silicon nitride, but is not limited thereto.

Referring to FIGS. 2A to 2C, the concentration profile of the diffused metal that is included in the first gate insulating film 110 will be described.

FIGS. 2A to 2C are schematic graphs explaining the concentration profile of the diffused metal but are not limited thereto. For convenience in explanation, in FIGS. 2A to 2C, the first lower gate insulating film 112 is indicated as an intermediate layer (IL), and the first upper gate insulating film 114 is indicated as a high-k layer (high-k).

Further, the diffused metal included in the first gate insulating film 110 may be one of the metal elements included in the first lower laminated body 120, but for convenience, explanation will be made on the assumption that the diffused metal is an aluminum element.

Referring to FIG. 2A, the concentration profile of the aluminum element in the first gate insulating film 110 includes a maximal point and a minimal point. That is, at least a part of the first gate insulating film 110 includes an aluminum element concentration that corresponds to the concentration of the maximal point, and at least a part of the first gate insulating film 110 includes an aluminum element concentration that corresponds to the concentration of the minimal point.

The concentration of the maximal point of the aluminum element may be positioned in the first lower gate insulating film 112 of the first gate insulating film 110. In other words, the concentration of the aluminum element in at least a part of the first lower gate insulating film 112 is higher than the concentration of the aluminum element on the boundary between the first lower gate insulating film 112 and the first upper gate insulating film 114.

FIG. 2A illustrates that the concentration of the minimal point of the aluminum element is positioned in the first upper gate insulating film 114, but is not limited thereto. Further, the concentration of the minimal point of the aluminum element in the first gate insulating film 110 does not necessarily represent the minimum concentration of the aluminum element in the first gate insulating film 110.

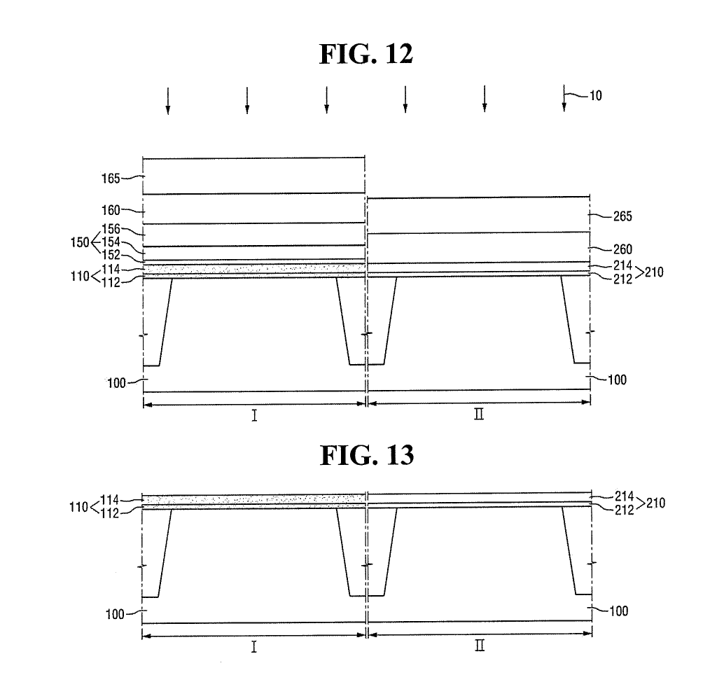

The fact that the concentration profile of the aluminum element in the first gate insulating film 110 has the maximal point and the minimal point means that the aluminum element in the first gate insulating film 110 is not caused by the diffusion that occurs due to the concentration difference. In other words, it means that at least a part of the aluminum element that is included in the first gate insulating film 110 is diffused into the first gate insulating film 110 by an intentional diffusion process. The details thereof will be described with reference to FIG. 12.

By the intentional diffusion process, the aluminum element is piled up in the first gate insulating film 110 that forms a boundary with the substrate 100. If the aluminum element in the first gate insulating film 110 is piled up, the threshold voltage of the transistor that includes the first gate insulating film 110 and the first lower laminated body 120 can be adjusted.

Referring to FIG. 2B, the concentration profile of the aluminum element in the first gate insulating film 110 includes a maximal point and a minimal point.

However, unlike FIG. 2A, the concentration of the maximal point of the aluminum element may be positioned in the first lower gate insulating film 112 of the first gate insulating film 110. In other words, the concentration of the aluminum element in the first lower gate insulating film 112 may be the highest on the boundary between the first lower gate insulating film 112 and the first upper gate insulating film 114.

That is, the maximal point and the minimal point of the concentration profile of the aluminum element in the first gate insulating film 110 may be positioned in the first upper gate insulating film 114.

As illustrated in FIGS. 2A and 2B, the maximal point of the concentration profile of the aluminum element in the first gate insulating film 110 may be positioned on the boundary between the first lower gate insulating film 112 and the first upper gate insulating film 114.

Referring to FIG. 2C, the concentration profile of the aluminum element in the first gate insulating film 110 may have the minimal point only. The concentration of the aluminum element in the first lower gate insulating film 112 may have the maximum value in the vicinity that forms the boundary with the substrate.

Further, FIG. 2A illustrates that the concentration of the minimal point of the aluminum element is positioned in the first upper gate insulating film 114, but is not limited thereto.

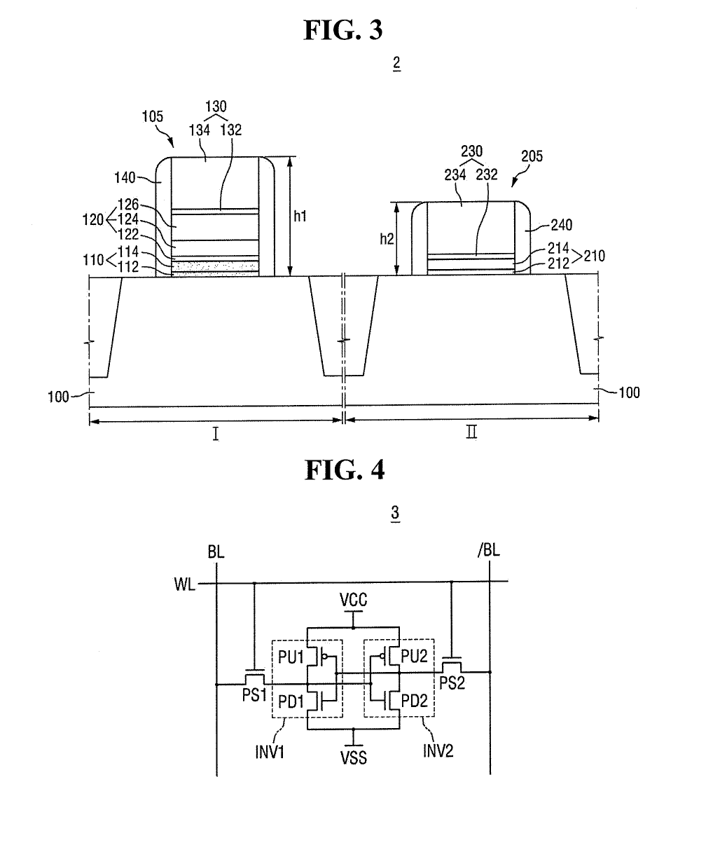

Referring to FIG. 3, a semiconductor device according to a second embodiment of the present inventive concepts will be described.

FIG. 3 is a view illustrating a semiconductor device according to a second embodiment of the present inventive concepts. For convenience in explanation, duplicate portions in FIG. 1 will be briefly explained or will be omitted.

Referring to FIG. 3, a semiconductor device 2 according to the second embodiment of the present inventive concepts includes a substrate 100, a first gate laminated body 105, and a second gate laminated body 205.

The substrate 100 includes a first region I and a second region II. The first region I may include a region in which a P-type transistor is formed, and the second region II may include a region in which an N-type transistor is formed.

The first gate laminated body 105 is formed on the first region I. The first gate laminated body 105 includes a first gate insulating film 110 including a high-k dielectric film, a first lower laminated body 120, and a first upper laminated body 130. The first gate insulating film 110, the first lower laminated body 120, and the first upper laminated body 130 are sequentially laminated on the substrate 100.

The first gate insulating film 110 is disposed on the first region I of the substrate 100, and is formed to come in contact with the substrate 100. Further, the first gate insulating film 110 includes diffused metal included in the first lower laminated body 120—specifically, an aluminum element, therein. The concentration profile of the aluminum element in the first gate insulating film 110 includes a maximal point and a minimal point. In other words, the aluminum element is piled up in at least a part of the first gate insulating film 110 that forms a boundary with the substrate 100.

The second gate laminated body 205 is formed on the second region II. The second gate laminated body 205 includes a second gate insulating film 210 including a high-k material and a second laminated body 230 that is disposed on the second gate insulating film 210.

The second gate insulating film 210 is disposed on the second region II of the substrate 100 and is formed in contact with the substrate 100. The second gate insulating film 210 may include a second lower gate insulating film 212 and a second upper gate insulating film 214. Further, the second gate insulating film 210 may include the same metal as is included in the second laminated body 230, to be described hereinafter.

The second lower gate insulating film 212 may be formed to come in contact with the substrate 100 and may be an intermediate layer between the substrate 100 and the second upper gate insulating film 214 like the first lower gate insulating film 112. The second upper gate insulating film 214 is disposed on the second lower gate insulating film 212 and includes a high-k dielectric film, as is included in the first upper gate insulating film 114.

The second laminated body 230 is disposed on the second gate insulating film 210. The second laminated body 230 may include a second insertion film 232 and a second metallic film 234. The second insertion film 232 and the second metallic film 234 are sequentially laminated on the second gate insulating film 210.

The second laminated body 230 is formed at the same level as the first upper laminated body 130. Here, “the same level” means that they are formed in the same fabrication step. That is, the second insertion film 232 may include, for example, lanthanum, and in particular embodiments, lanthanum oxide (LaO). Further, the second metallic film 234 may include, for example, at least one of the following: titanium nitride, tantalum carbide, tantalum nitride, and tantalum carbonitride.

At least one metal element that is included in the second gate insulating film 210 may be lanthanum (La), which can also be among the metal elements included in the second laminated body 230.

Unlike the first gate laminated body 105, the second gate laminated body 205 does not include a first lower laminated body 120 between the second insulating gate film 210 and the second laminated body 230.

The second insertion film 232 included in the second laminated body 230 may be used as the gate insulating film of the transistor together with the second gate insulating film 210. However, unlike the second insertion film 232, the second metallic film 234 included in the second laminated body 230 may be used as the gate electrode of the transistor.

A second spacer 240 is disposed on a side wall of the second gate laminated body 205 that is formed on the second region II. The second spacer 240 may include, for example, silicon oxide, silicon oxynitride, or silicon nitride, but is not limited thereto.

In the semiconductor device according to the second embodiment of the present inventive concepts, the portions of the substrate 100 that contact the first gate insulating film 110 and the second gate insulating film 210 may include the same material. For example, if the portion of the substrate 100 of the first region I that contacts the first gate insulating film 110 is silicon, the portion of the substrate 100 of the second region II that contacts the second gate insulating film 210 is also silicon.

In FIG. 3, the height of the first gate laminated body 105 is the first height, h1; and the height of the second gate laminated body 205 is the second height, h2. Here, the height, h1, of the first gate laminated body 105 is the height from the upper surface of the substrate 100 to the top of the first upper metallic film 134; and the height, h2, of the second gate laminated body 205 is the height from the upper surface of the substrate 100 to the top of the second metallic film 234. Since the second gate laminated body 205 does not include the first lower laminated body 120 that is included in the first gate laminated body 105, the height, h1, of the first gate laminated body 105 is higher than the height, h2, of the second gate laminated body 205.

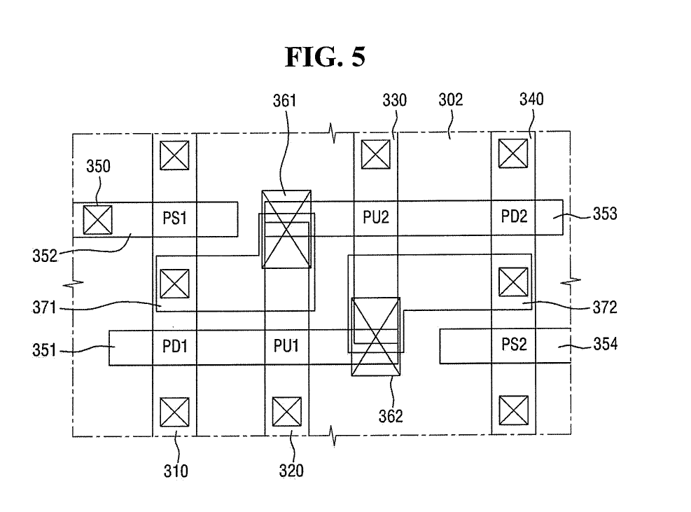

FIGS. 4 and 5 are a circuit diagram and a layout diagram of a semiconductor device according to a third embodiment of the present inventive concepts.

Referring to FIGS. 4 and 5, a semiconductor device 3 according to the third embodiment of the present inventive concepts may include a pair of inverters, INV1 and INV2, connected in parallel between a power supply node, Vcc, and a ground node, Vss; and a first path transistor, PS1, and a second pass transistor, PS2, connected to output nodes of the respective inverters, INV1 and INV2. The first pass transistor, PS1, and the second pass transistor, PS2, may be connected to a bit line, BL, and a complementary bit line, /BL, respectively. Gates of the first pass transistor, PS1, and the second pass transistor, PS2, may be connected to a word line, WL.

The first inverter, INV1, includes a first pull-up transistor, PU1, and a first pull-down transistor, PD1, which are connected in series; and the second inverter, INV2, includes a second pull-up transistor, PU2, and a second pull-down transistor, PD2, which are connected in series. The first pull-up transistor, PU1, and the second pull-up transistor, PU2, may be positive metal-oxide semiconductor (PMOS) transistors; and the first pull-down transistor, PD1, and the second pull-down transistor, PD2, may be negative metal-oxide semiconductor (NMOS) transistors.

Further, the first inverter, INV1, and the second inverter, INV2, may constitute one latch circuit in a manner that an input node of the first inverter, INV1, is connected to an output node of the second inverter, INV2; and an input node of the second inverter, INV2, is connected to an output node of the first inverter, INV1.

Here, referring to FIGS. 4 and 5, a first active region 310, a second active region 320, a third active region 330, and a fourth active region 340, which are spaced apart from each other, are formed to extend length-wise in one direction (for example, in the upper/lower direction in FIG. 5). The extending length of the second active region 320 and the third active region 330 may be shorter than the extending length of the first active region 310 and the fourth active region 340.

Further, a first gate electrode 351, a second gate electrode 352, a third gate electrode 353, and a fourth gate electrode 354 extend length-wise in the other direction (for example, in the right/left direction in FIG. 5) and are formed to cross the first to fourth active regions 310 to 340. Specifically, the first gate electrode 351 may be formed to completely cross the first active region 310 and the second active region 320 and to overlap a part of a vertical end of the third active region 330. The third gate electrode 353 may be formed to completely cross the fourth active region 340 and the third active region 330 and to overlap a part of a vertical end of the second active region 320. The second gate electrode 352 and the fourth gate electrode 354 may be formed to cross the first active region 310 and the fourth active region 340, respectively.

As illustrated, the first pull-up transistor, PU1, is defined around a region where the first gate electrode 351 and the second active region 320 cross each other, the first pull-down transistor, PD1, is defined around a region where the first gate electrode 351 and the first active region 310 cross each other, and the first pass transistor, PS1, is defined around a region where the second gate electrode 352 and the first active region 310 cross each other. The second pull-up transistor, PU2, is defined around a region where the third gate electrode 353 and the third active region 330 cross each other; the second pull-down transistor, PD2, is defined around a region where the third gate electrode 353 and the fourth active region 340 cross each other; and the second pass transistor, PS2, is defined around a region where the fourth gate electrode 354 and the fourth active region 340 cross each other.

Although not clearly illustrated, the source/drain may be formed on both sides of a region where the first to fourth gate electrodes 351 to 354 and the first to fourth active regions 310, 320, 330, and 340 cross each other.

Further, a plurality of contacts 350 may be formed. In addition, a shared contact 361 simultaneously connects the second active region 320, the third gate electrode 353, and a wiring 371. Furthermore, a shared contact 362 simultaneously connects the third active region 330, the first gate electrode 351, and a wiring 372.

For example, the first pull-up transistor, PU1, and the second pull-up transistor, PU2, may have a configuration as shown in FIG. 1; and the first pull-down transistor, PD1; the first pass transistor, PS1; the second pull-down transistor, PD2; and the second pass transistor, PS2, may have a configuration including a gate formed on the second region II, as shown in FIG. 3.

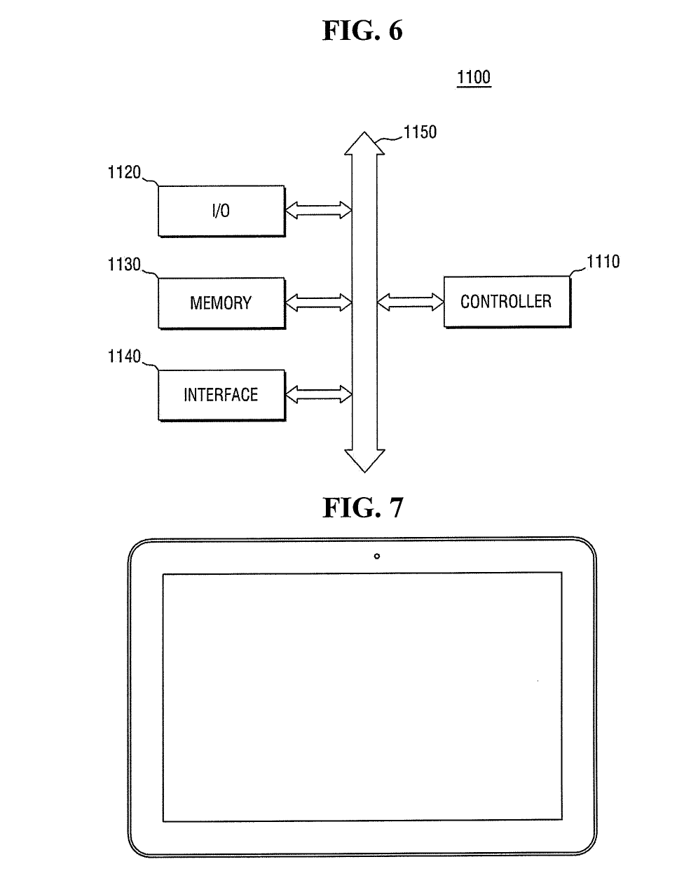

A block diagram of an electronic system including a semiconductor device according to some embodiments of the present inventive concepts is shown in FIG. 6, wherein an electronic system 1100 according to an embodiment of the present inventive concepts may include a controller 1110, an input/output (I/O) device 1120, a memory 1130, an interface 1140, and a bus 1150. The controller 1110, the I/O device 1120, the memory 1130, and/or the interface 1140 may be coupled to one another through the bus 1150. The bus 1150 corresponds to paths through which data is transferred.

The controller 1110 may include at least one of the following: a microprocessor, a digital signal processor, a microcontroller, and logic elements that can perform similar functions. The I/O device 1120 may include a keypad, a keyboard, and a display device. The memory 1130 may non-transitorily store data and/or commands. The interface 1140 may function to transfer the data to a communication network or to receive the data from the communication network. The interface 1140 may be of a wired or wireless type. For example, the interface 1140 may include an antenna or a wire/wireless transceiver. Although not illustrated, the electronic system 1100 may further include a high-speed dynamic random-access memory (DRAM) and/or static random-access memory (SRAM) as an operating memory for improving the operation of the controller 1110. A fin field-effect transistor according to embodiments of the present inventive concepts may be provided inside the memory 1130 or may be provided as a part of the controller 1110 and the I/O device 1120.

The electronic system 1100 may be incorporated in a personal digital assistant (PDA), a portable computer, a web tablet, a wireless phone, a mobile phone, a digital music player, a memory card, or all electronic devices that can transmit and/or receive information in wireless environments.

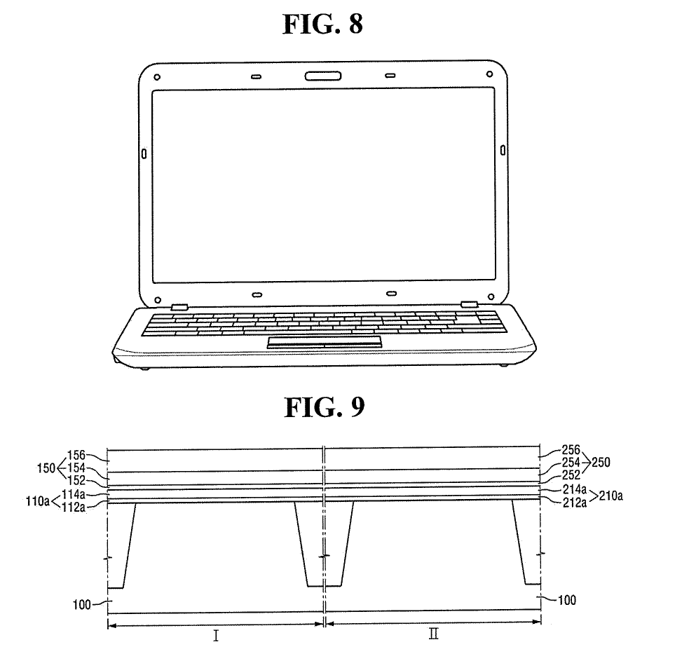

FIGS. 7 and 8 are exemplary views of a semiconductor system to which the semiconductor device according to some embodiments of the present inventive concepts can be applied. FIG. 7 illustrates a tablet personal computer (PC), and FIG. 8 illustrates a notebook PC. At least one of the semiconductor devices 1 to 3 according to the embodiments of the present inventive concepts may be included in the tablet PC or the notebook PC. It is apparent to those of skilled in the art that the semiconductor device according to some embodiments of the present inventive concepts can also be included in other integrated circuit devices that have not been exemplified.

Referring to FIGS. 3 and 9 to 15, a method for fabricating a semiconductor device according to an embodiment of the present inventive concepts will be described. FIGS. 9 to 15 are views of intermediate steps explaining a method for fabricating a semiconductor device according to an embodiment of the present inventive concepts.

Referring to FIG. 9, on the substrate 100 including the first region I and the second region II, pre-gate insulating films 110a and 210a that include high-k dielectric films are formed. Sacrificial laminated bodies 150 and 250 are formed on the pre-gate insulating films 110a and 210a.

On the first region I of the substrate 100, the first pre-gate insulating film 110a and the first sacrificial laminated body 150 are sequentially formed (resulting in the first pre-gate insulating film 110a being sandwiched between the first sacrificial laminated body 150 and the substrate 100); and on the second region II of the substrate 100, the second pre-gate insulating film 210a and the second sacrificial laminated body 250 are sequentially formed (resulting in the second pre-gate insulating film 201a being sandwiched between the second sacrificial body 250 and the substrate 100).

The first pre-gate insulating film 110a includes a first lower pre-gate insulating film 112a and a first upper pre-gate insulating film 114a including the high-k dielectric film; and the second pre-gate insulating film 210a includes a second lower pre-gate insulating film 212a and a second upper pre-gate insulating film 214a including the high-k dielectric film.

In particular embodiments, the lower pre-gate insulating films 112a and 212a and the upper pre-gate insulating films 114a and 214a are sequentially formed on the substrate 100 [resulting in the lower pre-gate insulating films 112a and 212a being respectively sandwiched between (a) the upper pre-gate insulating films 114a and 214a and (b) the substrate 100]. The lower pre-gate insulating films 112a and 212a may include silicon oxide (e.g., SiO₂) films and for example, may be formed using a chemical oxidation method, a UV oxidation method, or a dual plasma oxidation method.

Thereafter, the upper pre-gate insulating films 114a and 214a including the high-k dielectric films are formed on the lower pre-gate insulating films 112a and 212a. The upper pre-gate insulating films 114a and 214a may be formed using, for example, a chemical vapor deposition (CVD), an atomic layer deposition (ALD), or sputtering, but is not limited thereto.

Thereafter, the sacrificial laminated bodies 150 and 250 are formed on the upper pre-gate insulating films 114a and 214a. That is, lower sacrificial films 152 and 252, intermediate sacrificial films 154 and 254, and upper sacrificial films 156 and 256 are sequentially formed (in the order recited) on the pre-gate insulating films 114a and 214a.

The lower sacrificial films 152 and 252 and the upper sacrificial films 156 and 256 may include, for example, at least one of the following: titanium nitride, tantalum carbide, tantalum nitride, and tantalum carbonitride. The intermediate sacrificial films 154 and 254 may include, for example, aluminum and, in particular embodiments, may include aluminum films.

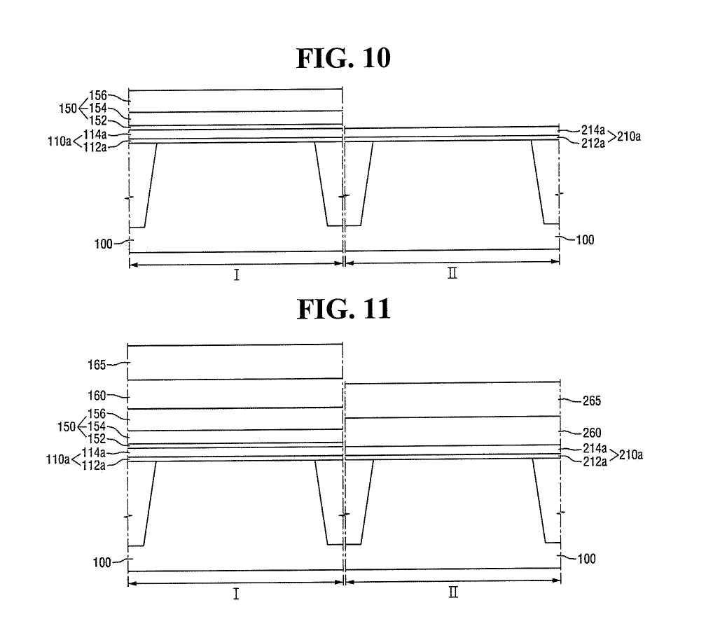

Referring to FIG. 10, by removing the second sacrificial laminated body 250 that is formed on the second region II, the second pre-gate insulating film 210a is exposed.

First, a mask pattern for exposing the second region II is formed on the substrate 100. The mask pattern may include, for example, a photosensitive film pattern.

Thereafter, using the mask pattern, the second sacrificial laminated body 250 that is formed on the second region II is removed. By removing the second sacrificial laminated body 250, the second upper pre-gate insulating film 214a is exposed. The second sacrificial laminated body 250 may be removed using, for example, wet etching, but is not limited thereto.

Thereafter, by removing the mask pattern, the first sacrificial laminated body is exposed. Through this process, the first sacrificial laminated body 150 still remains on the first pre-gate insulating film 110a that is formed on the first region I; and the second sacrificial laminated body 250 is removed from the second pre-gate insulating film 210a of the second region II.

Referring to FIG. 11, lower capping films 160 and 260 and then upper capping films 165 and 265 are sequentially formed on the substrate 100.

The lower capping films 160 and 260 may be entirely formed on the first region I and on the second region II. The lower capping films 160 and 260 may include a metallic material and, for example, may include titanium nitride. The upper capping films 165 and 265 may include, for example, polysilicon.

Referring to FIG. 12, by performing a heat treatment 10 with respect to the first sacrificial laminated body 150, the first gate insulting film 110 is formed.

In other words, through the application of thermal energy in heat treatment 10, metal elements included in the first sacrificial laminated body 150 are diffused into the first pre-gate insulating film 110a. As a consequence of this diffusion, the first gate insulating film 110 that includes the metal elements included in the first sacrificial laminated body 150 is formed on the first region I.

In particular embodiments, aluminum, which is one of the metal elements included in the first sacrificial laminated body 150, is diffused into the first upper pre-gate insulating film 114a and into the first lower pre-gate insulating film 112a while the heat treatment 10 is performed. The diffused metal, however, is not limited to aluminum, as titanium (Ti) or tantalum (Ta) that is included in the first sacrificial laminated body 150 may also be diffused into the first pre-gate insulating film 110a. As aluminum is diffused into the first pre-gate insulating film 110a, the first gate insulating film 110 is formed.

While the first gate insulating film 110 is formed on the first region I, the second gate insulating film 210 is formed on the second region II. The second gate insulating film 210 may include the same components as the second pre-gate insulating film 210a but is not limited thereto. That is, a part of titanium that is included in the second lower capping film 260 may be diffused into the second pre-gate insulating film 210a. As a consequence of this diffusion, the second gate insulating film 210 may include titanium.

The first sacrificial laminated body 150, including aluminum, remains on the first gate insulating film 110; but the second sacrificial laminated body 250, including aluminum, does not remain on the second gate insulating film 210. Accordingly, the first gate insulating film 110 includes aluminum that is artificially diffused into the first gate insulating film 110, but the second gate insulating film 210 does not include aluminum.

Referring to FIG. 13, by removing the first sacrificial laminated body 150, the lower capping films 160 and 260, and the upper capping films 165 and 265, the first gate insulating film 110 and the second gate insulating film 210 are exposed.

That is, the first sacrificial laminated body 150, the first lower capping film 160, and the first upper capping film 165 are removed from the first region I; and the second lower capping film 260 and the second upper capping film 265 are removed from the second region II.

The first sacrificial laminated body 150, the lower capping films 160 and 260, and the upper capping films 165 and 265 may be removed using, for example, wet etching, but their removal is not limited thereto.

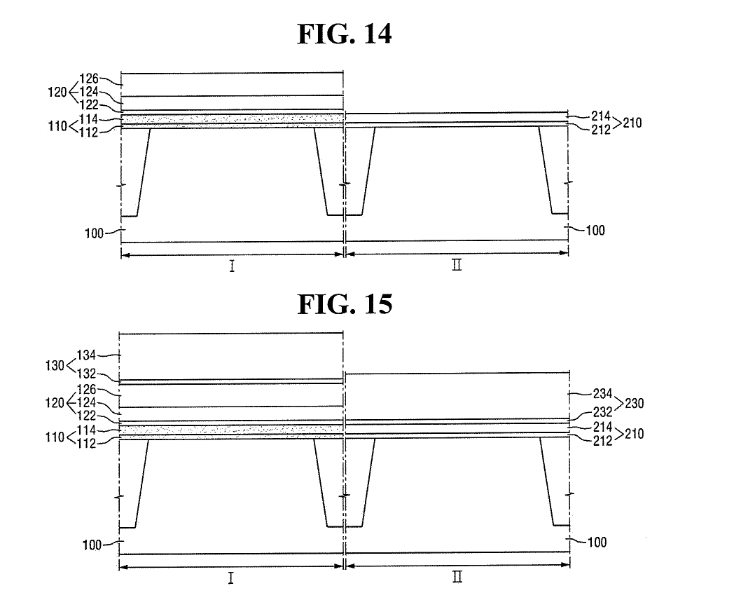

Referring to FIG. 14, the first lower laminated body 120 is formed on the first gate insulating film 110 of the first region I. However, the first lower laminated body is not formed on the second gate insulating film 210 of the second region II.

In particular embodiments, the first lower laminated body 120 is entirely formed on the substrate 100 that includes the first region I and the second region II. Thereafter, a mask pattern for exposing the second region II is formed on the substrate 100. That is, the first region I is covered by the mask pattern. Using the mask pattern, the first lower laminated body 120 that is formed on the second region II is removed. By removing the first lower laminated body 120 of the second region II, the second gate insulating film 210 is exposed.

The first lower laminated body 120 may be patterned using, for example, wet etching, but the method for patterning is not limited thereto.

Referring to FIG. 15, the first upper laminated body 130 and the second laminated body 230 are respectively formed on the first region I and the second region II. That is, the first upper laminated body 130 is formed on the first lower laminated body 120, and the second laminated body 230 is formed on the second gate insulating film 210.

The first upper laminated body 130 and the second laminated body 230, which are respectively formed on the first region I and the second region II, are formed at the same level (i.e., in the same fabrication step).

Referring again to FIG. 3, the first gate laminated body 105 is formed by patterning the first gate insulating film 110, the first lower laminated body 120, and the first upper laminated body 130, each of which are formed on the first region I. Further, the second gate laminated body 205 is formed by patterning the second gate insulating film 210 and the second laminated body 230, each of which are formed on the second region II.

Thereafter, the first spacer 140 and the second spacer 240 are formed on the side walls of the first gate laminated body 105 and the second gate laminated body 205.

In the process of forming the first gate laminated body 105 and the second gate laminated body 205 and in the process of forming the first spacer 140 and the second spacer 240, a part of the diffused metal film 124 that is included in the first lower laminated body 120 may be diffused into the first gate insulating film 110. As a result of this diffusion, the aluminum concentration profile in the first gate insulating film 110 may include the maximal point and the minimal point.

Further, in the process of forming the first gate laminated body 105 and the second gate laminated body 205 and in the process of forming the first spacer 140 and the second spacer 240, a part of the metal element of the second insertion film 232 that is included in the second laminated body 230 may be diffused into the second gate insulating film 210. As a result of this diffusion, the second gate insulating film 210 may include lanthanum.

Although preferred embodiments of the present inventive concepts have been described for illustrative purposes, those skilled in the art will appreciate that various modifications, additions and substitutions are possible, without departing from the scope and spirit of the invention as disclosed in the accompanying claims.

What is claimed is:

1. A semiconductor device, comprising:
a substrate including a first region and a second region; and
first and second gate laminated bodies respectively formed on the first region and the second region,
wherein the first gate laminated body includes:
a first gate insulating film in contact with the substrate, wherein the first gate insulating film includes a first high-k dielectric film;
a first lower laminated body on the first gate insulating film, wherein the first lower laminated body includes a first titanium nitride film, an aluminum film, and a second titanium nitride film, wherein the first titanium nitride film is between the aluminum film and the first gate insulating film, and wherein the aluminum film is between the second titanium nitride film and the first titanium nitride film; and
a first upper laminated body on the first lower laminated body; and
wherein the second gate laminated body includes:
a second gate insulating film in contact with the substrate, wherein the second gate laminated body includes a second high-k dielectric film; and
a second laminated body formed on the second gate insulating film.

2. The semiconductor device of claim 1, wherein the first gate insulating film includes aluminum.

3. The semiconductor device of claim 2, wherein a concentration profile of the aluminum includes a maximal point and a minimal point in the first gate insulating film.

4. The semiconductor device of claim 2, wherein the aluminum is piled up in the first gate insulating film to form a boundary with the substrate.

5. The semiconductor device of claim 1, wherein the first upper laminated body and the second laminated body comprise a metal oxide film and a metal nitride film, wherein the metal oxide film is between the metal nitride film and the first lower laminated body.

6. The semiconductor device of claim 5, wherein the metal oxide film includes lanthanum oxide, and wherein the metal nitride film includes titanium nitride.

7. The semiconductor device of claim 6, wherein the second gate insulating film includes lanthanum (La).

8. The semiconductor device of claim 1, wherein the first region includes a P-type transistor region, and wherein the second region includes an N-type transistor region.

9. The semiconductor device of claim 1, wherein the second laminated body is formed at the same level as the first upper laminated body.

10. A semiconductor device, comprising:
a first gate insulating film in contact with a substrate and doped with diffused metal;
a second gate insulating film including a high-k dielectric film on the first gate insulating film, the diffused metal being doped in the high-k dielectric film; and
a first laminated body including a diffused metal film on the second gate insulating film.

11. The semiconductor device of claim 10, wherein the diffused metal film includes aluminum (Al).

12. The semiconductor device of claim 10, wherein a concentration profile of the diffused metal includes a maximal point and a minimal point in the first gate insulating film and the second gate insulating film.

13. The semiconductor device of claim 10, wherein the first laminated body comprises metallic films respectively disposed on upper and lower portions of the diffused metal film.

14. The semiconductor device of claim 13, wherein the first laminated body comprises a first titanium nitride (TiN) film, an aluminum (Al) film, and a second titanium nitride film, wherein the first titanium nitride film is between the second gate insulating film and the aluminum film, and wherein the aluminum film is between first and second titanium nitride films.

15. The semiconductor device of claim 10, further comprising a second laminated body including a metal oxide film and a metallic film on the first laminated body.

16. The semiconductor device of claim 15, wherein the second laminated body comprises a lanthanum oxide (LaO) film and a titanium nitride film, wherein the lanthanum oxide film is between the first laminated body and the titanium nitride film.

17. A semiconductor device, comprising:
a substrate;
a lower gate insulating film coated on the substrate and doped with aluminum;
an upper gate insulating film coated on the lower gate insulating film, with the lower gate insulating film being sandwiched between the substrate and the upper gate insulating film, wherein the upper gate insulating film includes a dielectric film doped with aluminum, wherein the dielectric film has a dielectric constant higher than that of the substrate; and
a laminated body including an aluminum film on the upper gate insulating film.

18. The semiconductor device of claim 17, wherein the laminated body further includes a first titanium nitride film and a second titanium nitride film, wherein the aluminum film is sandwiched between first and second titanium nitride films.

19. The semiconductor device of claim 18, wherein the laminated body on the upper gate insulation film is a lower laminated body, the device further comprising an upper laminated body including a metal oxide film and a metallic film on the lower laminated body, wherein the metal oxide film is sandwiched between the metallic film and the lower laminated body.

20. The semiconductor device of claim 17, wherein the device is free of a silicon-germanium layer.
